(19) United States
(12) Patent Application Publication
(10) Pub. No.: US 2011/0309847 A1
(43) Pub. Date: Dec. 22, 2011

(54) High Current Kelvin Connections and Contact Resistance Verification Method

(76) Inventors: Rodney Schwartz, Tiki Island, TX (US); Gary Rogers, Mesa, AZ (US); Steve Clauter, Tempe, AZ (US)

(21) Appl. No.: 13/090,771

(22) Filed: Apr. 20, 2011

Related U.S. Application Data
(60) Provisional application No. 61/355,804, filed on Jun. 17, 2010.

(51) Int. Cl. G01R 27/08

(52) U.S. Cl. 324/713; 324/722

(57) ABSTRACT

A method and circuit is provided for implementing high current capability Kelvin connections and measuring the resistance of the contacts and connections to verify that the conducting path is capable of carrying the high current without damage or degraded performance. Included as well is the means and circuit for efficiently dividing a high current test stimulus current into 2 or more paths with low losses and voltage drops.

### RELATED APPLICATION DATA

This application claims priority of U.S. Provisional Application No. 61/355,804 filed on Jun. 17, 2010, which is incorporated herein by reference in its entirety.

### TECHNICAL FIELD OF THE INVENTION

The present invention relates generally to testing of integrated circuits and power semiconductor devices, and more particularly, to a method and apparatus for implementing Kelvin connections with verification and contact resistance testing capability that is especially useful for high current and high speed applications.

### DESCRIPTION OF THE RELATED ART

Precision measurement circuits often make use of Kelvin connections (see, e.g., FIG. 1) to provide high current capability and accurate measurements by reducing or removing the effect of current flowing through the contact resistance in series with the measurement stimuli. A force lead connection 10 is typically used to supply the stimuli, and a sense lead 12, which is simply a connection that carries no current, is used to make the measurement. Because the sense lead 12 carries no or negligible current, the effect of voltage drop in the contacts and leads is eliminated. In a typical test application, dual contacts are made to each lead of the device under test. For integrated circuit chip packages and power semiconductor devices this is often done with a socket configuration having two separate spring contacts to each lead of the device. The force lead is typically connected to one contact and the sense lead to the other.

Testing to verify that the Kelvin connection is properly made confirms both leads are making proper contact. In other types of high current testing, both leads may be used as parallel paths for lower resistance and higher current carrying capacity. In this case, testing the “Kelvin connection” verifies that both leads 10, 12 are properly connected to the test point so both leads can pass high currents and share the load.

In testing of high current devices, a means is used to determine the integrity of the test connections with the device terminals to insure the leads actually are making contact and that the quality of the contact is satisfactory. Connections that have high resistance may cause inaccurate tests, or may damage test contacts. In some situations, high currents are passed to the device under test, while simultaneously, high voltages may be present. The circuitry for determining proper connection integrity must then also be able to withstand the presence of these high voltages during the course of the test. Typically, measurement circuits that can withstand high voltages are high impedance. However, testing for low values of contact resistance generally requires substantial measurement currents, which requires low impedance circuits.

In some high current testing applications a true sense Kelvin measurement is not required but the same dual contact system can be used to provide parallel high current paths. In this case, the contact resistance of both connections of the contact pair is important because both are passing high current. Splitting the current into two parallel paths has other beneficial effects such as lowering the overall path inductance and resistance. In these cases the current handling capability of individual contacts, such as socket contacts or handler contacts, may not be sufficient to handle the current required. Adding parallel contacts provides additional current handling capability. The problem with this approach is that it is difficult to efficiently divide the high current test stimulus into two different paths. Additionally, existing test circuits for verifying the contact integrity are not optimal. The requirement for very low contact resistance in high current paths makes it difficult to verify using existing methods.

Existing test circuits for verification of Kelvin contacts typically use active circuitry which floats with the measurement leads to verify the contact resistance. An example of this type circuitry using optical couplers 20 is shown in FIGS. 2a and 2b. These circuits use a significant number of components and have the disadvantage of requiring a floating power circuit 22, which may have significant capacitance to ground. For example, a typical 1 watt isolated DC/DC converter 22 might have 20-40 picofarads of capacitance through its isolation circuit to ground. This capacitance is a direct load on the stimulus signal. In addition, isolated DC/DC converters may be sensitive to the ramp rate (dv/dt) of any signal which moves the isolated voltage with respect to ground. This can cause reliability problems as well as circuit operation problems. In many cases a converter with a much higher isolation voltage specification than actually required by the application (5.7 kVDC or 6 kVDC versus 3 kVDC) must be specified to obtain the dv/dt performance required. These higher isolation voltage converters increase the cost of the circuit. This capacitive loading slows down any high speed voltage transitions. In addition, the circuit uses an optical coupler 20 to sense the Kelvin connection which may result in more than 100 microseconds to obtain the result. The power must remain on to the circuit at all times to prevent even slower operation caused by the turn on time of the DC/DC converter 22. The circuit is also hard programmed to detect a certain level of contact resistance to determine a failure.

Another example of a circuit designed to verify the quality of the Kelvin contact connections is incorporated in U.S. Pat. No. 5,999,002, Fasnacht et al, which is a continuation in part of U.S. Pat. No. 5,886,530. This circuit attempts to use a transformer to isolate the Kelvin contact resistance measurement from the test stimuli. The technique taught in U.S. Pat. No. 5,999,002 employs a simple single pulse applied to the primary of the transformer that is affected by the secondary resistance of the transformer including the contact resistance between the force and sense leads. The secondary of the transformer is capacitively coupled to the force and sense contacts to isolate the circuit from the measurement stimuli. Although difficult to follow, the techniques disclosed in U.S. Pat. No. 5,999,002 may have theoretically useful properties.

As best understood, the technique taught in U.S. Pat. No. 5,999,002, from a practical standpoint, has several problems. First, the secondary of the transformer must be capacitively coupled to the Kelvin contacts to isolate it from the measurement circuit. This creates capacitive loading on the measurement signals, which could degrade the quality of any dynamic measurements. Second, the resistance error threshold of any practical version of the circuit is quite high in comparison to the desired low resistance path of a high current Kelvin connection. In addition, the error threshold is fixed by component values and cannot be programmed or otherwise readily changed to different levels. The nature of the circuit used in U.S. Pat. No. 5,999,002 seriously limits the sensitivity of the resistance test, so it is difficult, if not impossible, to set tight limits on the contact resistance. In high current testing this can be a very significant problem. Since the circuit uses only a preprogrammed threshold to determine if the contact is good or bad, it does not provide any quantitative measurement of the actual level of the contact resistance. This may be extremely important and the actual requirements may vary with different levels of current required for testing different types of devices.

Accordingly, there is a need in the art for a fast, accurate method of verifying the contact resistance between the force and sense leads of a Kelvin connection. The method should be sensitive and accurate enough to discriminate very low resistance values to ensure the connection can pass very high currents, including the case where two parallel forcing leads are used to increase current capability with minimal capacitive loading. The method should also be able to provide measurement capability to determine the actual resistance value, not just a “comparison to limit” in order to accommodate the wide range of possible requirements in a single test station. Finally, the method should provide the best means to manage a high current test stimulus that is divided into two or more separate force paths with minimal losses and yet be able to verify the contact resistance at the Kelvin connection.

### SUMMARY

Accordingly, a method and system in accordance with the present invention enable integrity verification of Kelvin connections to an integrated circuit, power semiconductor device or other electronic assembly. Additionally, a method and system in accordance with the present invention enable measurement of actual contact resistance of a Kelvin connection. Further, a method and system in accordance with the present invention enable integrity verification of Kelvin connections in the presence of high voltages. In addition, a method and system in accordance with the present invention enable integrity verification of Kelvin connections without presenting significant capacitive loading, thereby improving high-speed voltage transitions relative to conventional circuits.

Also, a method and system in accordance with the present invention enable for a simple method of connecting to Kelvin connected leads that may be used to provide two or more parallel high current paths to a test point, and integrity verification of such connections.

According to one aspect of the invention, a device for measuring contact impedance includes: a transformer having a primary and secondary winding, the primary and secondary winding each having a respective first end, second end, and the primary winding including a center tap; an input device for receiving an electrical waveform, the input device electrically coupled to the first and second end of the primary winding; first and second test leads for connection to a device under test, the first and second test leads electrically connected to the first and second ends, respectively, of the secondary winding; a sensing device electrically coupled to the center tap of the primary winding and configured to provide a measurement corresponding to a contact impedance across at least one of the first and second test leads.

According to one aspect of the invention, the input device comprises a switching device configured to selectively couple the first and second end of the primary winding to the electrical waveform.

According to one aspect of the invention, the device further includes a waveform generator for generating the electrical waveform, the waveform generator operatively coupled to the input device.

According to one aspect of the invention, the waveform generator is configured to generate two alternating waveforms out of phase from one another, and the input device provides one of the two alternating waveforms to the first end of the primary winding, and the other of the two alternating waveforms to the second end of the primary winding.

According to one aspect of the invention, the sensing device is configured to measure a current flowing from the center tap of the primary winding to ground.

According to one aspect of the invention, the secondary winding includes a center tap, further comprising a stimulus test lead electrically connected to the center tap of the secondary winding and configured to receive a test signal.

According to one aspect of the invention, the device further includes a measurement lead different from the first and second test leads, the measurement lead configured to provide a measurement path for Kelvin connected measurements.

According to one aspect of the invention, the device further includes a comparator operatively coupled to the sensing device, the comparator configured to generate a signal indicative of the measured impedance being at least one of above or below a predetermined threshold.

According to one aspect of the invention, a device for measuring contact impedance includes: a transformer having a primary and secondary winding, the primary and secondary winding each having a respective first end and second end, the primary winding further including a center tap; an input device for receiving an electrical waveform, the input device electrically coupled to the first and second end of the primary winding; first and second test leads for connection to a device under test; a rectifier having an input with first and second input connections and an output with first and second output connections, the first and second input connections electrically connected to the first and second end of the secondary winding, respectively, and the first and second output connections connected to the first and second test leads, respectively; and a sensing device electrically coupled to the primary center tap and configured to provide a measurement corresponding to a contact impedance across at least one of the first and second test leads.

According to one aspect of the invention, the input device comprises a switching device configured to selectively couple the first and second end of the primary winding to the electrical waveform.

According to one aspect of the invention, the device further includes a waveform generator for generating the electrical waveform, the waveform generator operatively coupled to the input device.

According to one aspect of the invention, the waveform generator is configured to generate two alternating waveforms out of phase from one another, and the input device provides one of the two alternating waveforms to the first end of the primary winding, and the other of the two alternating waveforms to the second end of the primary winding.

According to one aspect of the invention, the sensing device is configured to measure a current flowing from the primary center tap to ground.

According to one aspect of the invention, the device further includes a measurement lead different from the first and second test leads, the measurement lead configured to provide a measurement path for Kelvin connected measurements.

According to one aspect of the invention, the device further includes a voltage clamping device connected between the first and second output connections of the rectifier, the voltage clamping means configured to prevent voltage on the first and second output connections from exceeding a predetermined voltage.

According to one aspect of the invention, the device further includes a comparator operatively coupled to the sensing device, the comparator configured generate a signal indicative of the measured impedance being at least one of above or below a predetermined threshold.

According to one aspect of the invention, a method for measuring contact impedance includes: connecting each end of a transformer secondary winding to a respective contact of a contact pair to be measured; applying an alternating current waveform to a primary winding of the transformer; sensing current flow in a center tap of the primary windings; and correlating the sensed current flow to the contact impedance.

According to one aspect of the invention, the method further includes applying a current stimulus to a center tap of the secondary winding.

According to one aspect of the invention, the method further includes comparing the sensed current flow to a predetermined value, and determining if the resistance of the contact pair is acceptable or unacceptable based on the comparison.

According to one aspect of the invention, the method further includes enabling application of current stimulus to the respective contacts of the contact pair when the resistance of the contact pair is acceptable, and inhibiting application of current stimulus to the respective contacts of the contact pair when the resistance of the contact pair is unacceptable.

According to one aspect of the invention, the method further includes monitoring the sensed current flow for an alternating current (AC) component, and concluding there is an imbalance between the respective contacts of the contact pair when the AC component is above a predetermined threshold.

According to one aspect of the invention, the method further includes: applying a test stimulus current to a center tap of the secondary winding; dividing the test stimulus current into at least two separate current paths; and providing the test stimulus current to a respective contact tip via the at least two separate current paths.

According to one aspect of the invention, the method further includes minimizing capacitance to ground at the test stimulus input to effect an increase in high-speed stimulus transitions.

According to one aspect of the invention, the method further includes a method for checking contact impedance includes: connecting secondary leads of a transformer secondary winding to input leads of a rectifier; connecting output leads of the rectifier to respective ones of a force and sense lead of a contact; applying an alternating current waveform to primary windings of the transformer; sensing current flowing to ground in a center tapped lead of the transformer primary windings; and correlating the sensed current flow to the contact impedance.

According to one aspect of the invention, the method further includes connecting a current stimulus device to one output of the rectifier, and connecting a Kelvin connected measurement device to the other output of the rectifier.

These and further features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the scope of the claims appended hereto.

Features that are described and/or illustrated with respect to one embodiment may be used in the same way or in a similar way in one or more other embodiments and/or in combination with or instead of the features of the other embodiments.

### BRIEF DESCRIPTION OF THE DRAWINGS

FIG. 1 is a schematic diagram of a conventional Kelvin connected measurement circuit.

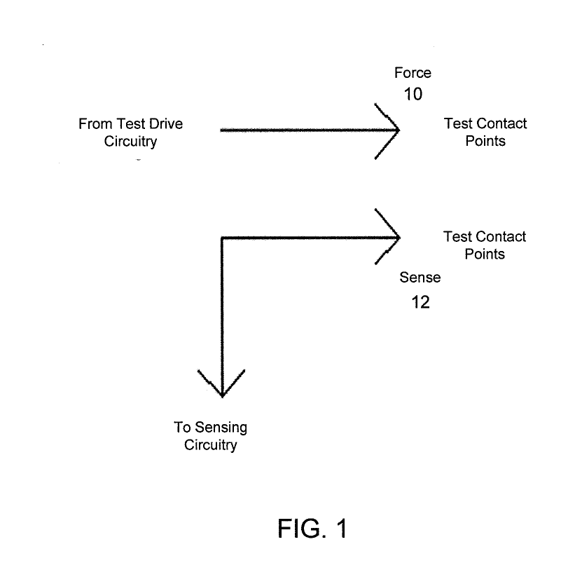

FIG. 2a is a schematic diagram of a conventional Kelvin verification circuit with separate Force and Sense Kelvin connections.

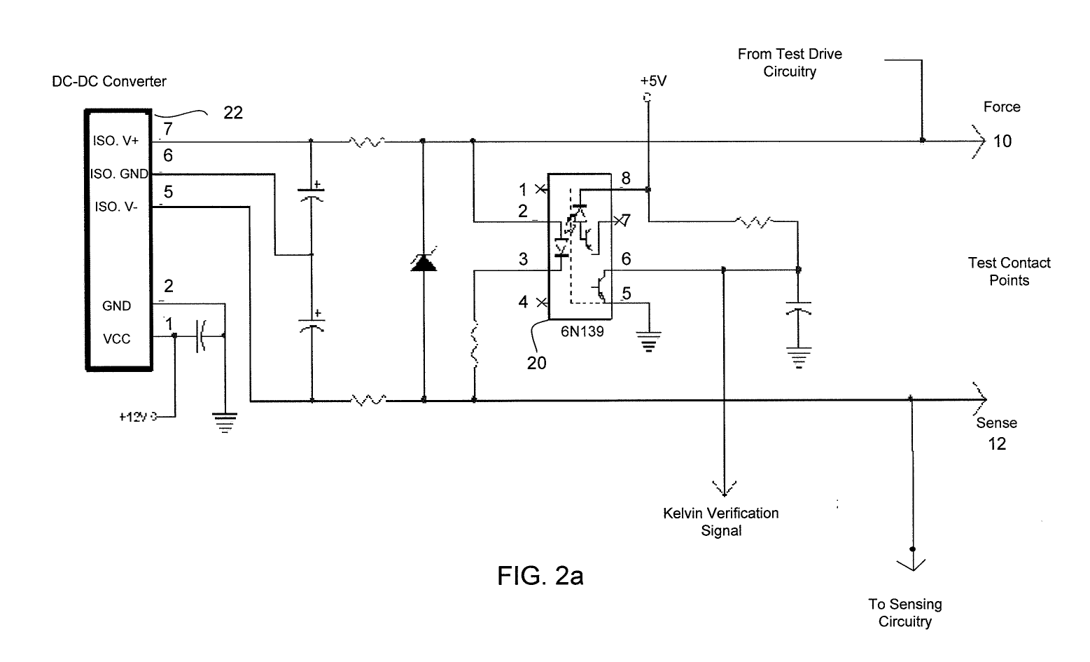

FIG. 2b is a schematic diagram of a conventional Kelvin verification circuit with two parallel high current, or Force, Kelvin connections from a single high current test stimulus. Therefore two Kelvin diodes are utilized to isolate the Force connections for Kelvin verification.

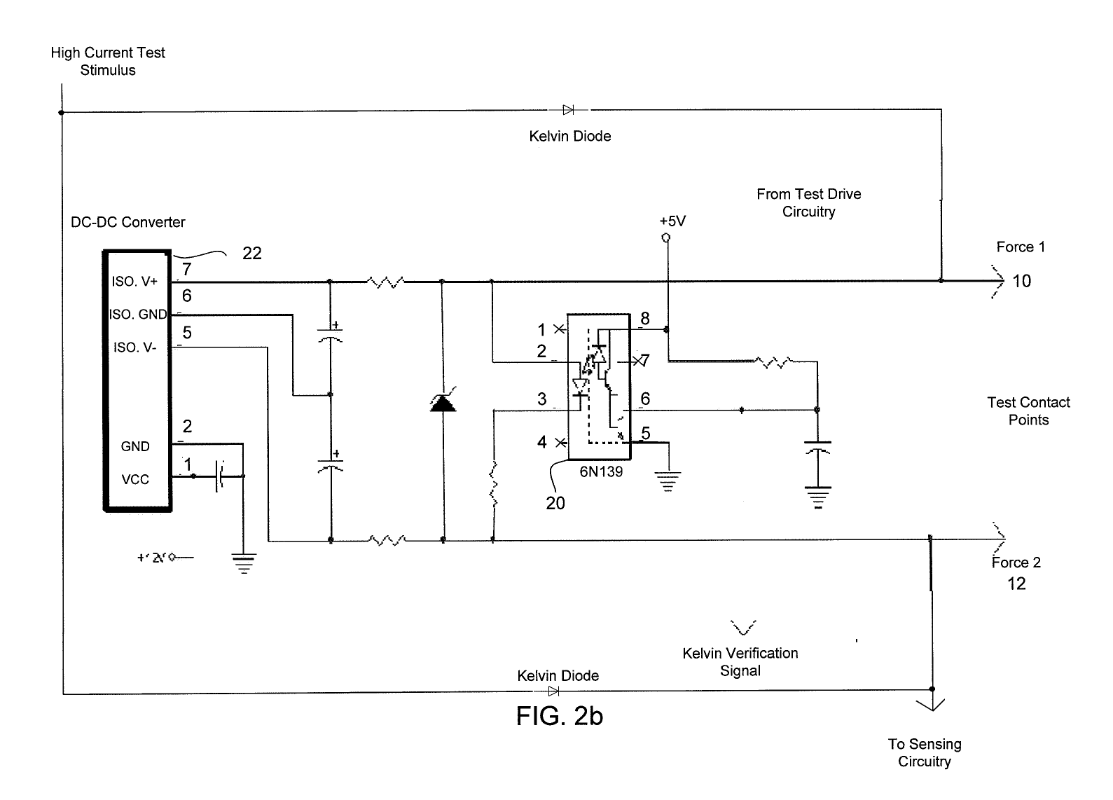

FIG. 3a is a schematic diagram of an exemplary high current Kelvin verification circuit in accordance with the present invention showing the Test Stimulus being divided into two parallel force paths without any Kelvin diodes.

FIG. 3b is a schematic diagram of an exemplary high current Kelvin verification circuit in accordance with the present invention which divides high current and Kelvin measurement into four equal force connections which can all be verified in accordance to the present invention.

FIG. 4 is a schematic diagram on another exemplary high current Kelvin verification circuit with added sense lead in accordance with the present invention.

FIG. 5 is a schematic diagram of yet another exemplary Kevin verification circuit with added bridge rectifier circuit to separate force and sense functions in accordance with the present invention.

FIG. 6 is a schematic diagram exemplary high current Kelvin verification circuit in accordance with the present invention which separates the test stimulus current into force and sense connections without the use of a bridge rectifier or other circuitry.

### DETAILED DESCRIPTION OF EMBODIMENTS

Embodiments of the present invention will now be described with reference to the drawings, wherein like reference numerals are used to refer to like elements throughout. It will be understood that the figures are not necessarily to scale.

A circuit has been developed that provides several advantages over previously employed circuitry. The advantages may include, for example:

1. relative simplicity

2. high voltage isolation

3. high current capability

4. maximal utilization of test contacts

5. variable threshold

6. ruggedness

7. low voltage and power losses

8. low capacitive loading

9. fast measurement of Kelvin resistance

10. adaptable Kelvin resistance measurements

11. multiple levels of current division

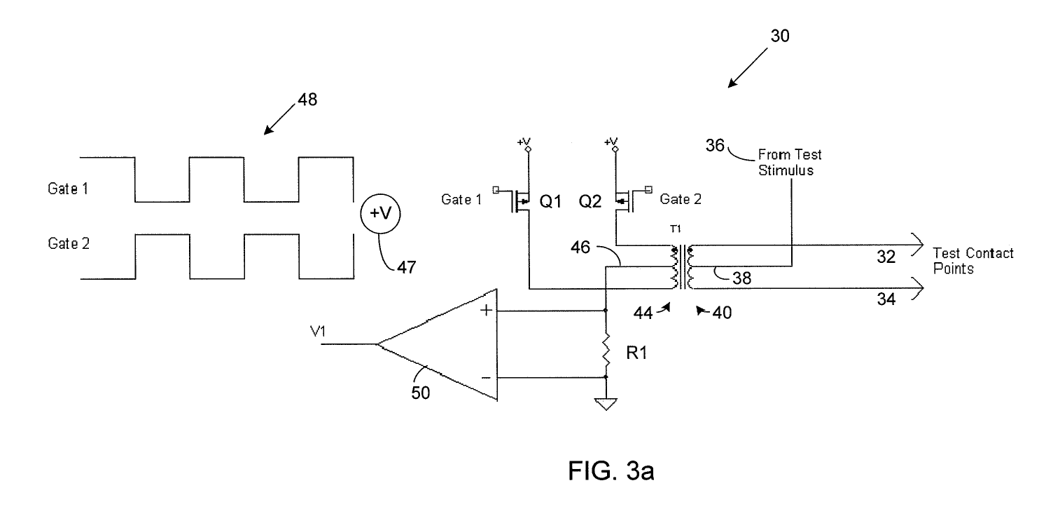

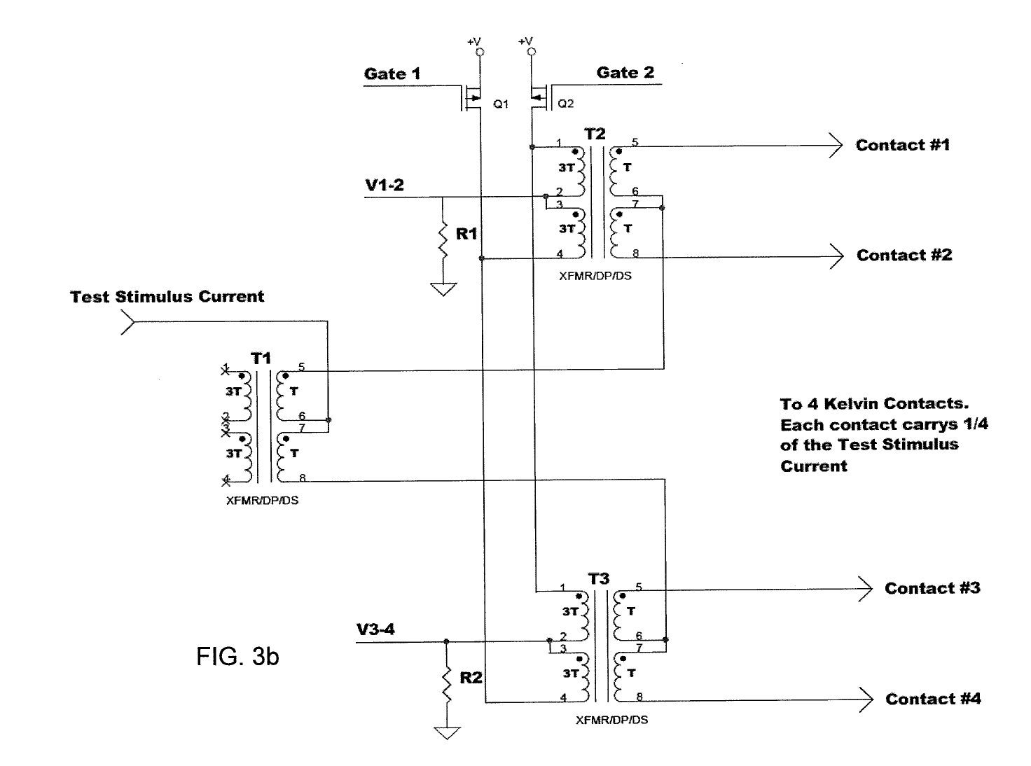

A preferred embodiment of a circuit 30 for high current capability is shown in FIG. 3a. Test contact points 32, 34 are the contacts that will be connecting to the device under test and the contact resistance of these connections will be determined via the circuit shown. Note Kelvin diodes are not needed.

A test stimulus, such as current stimulus having a predetermined magnitude, can be provided on line 36 from the high current source that will be used in testing of the device. As can be seen in FIG. 3a, the test stimulus is applied to a center tap 38 on a secondary winding 40 of a transformer T1. This winding is preferably constructed with heavy gauge wire so that it can pass the high test currents. The applied test stimulus 36 will then approximately divide with low losses and pass on to each of the test contact points 32, 34. Therefore, both contact points may be used for passing currents resulting from the test stimulus 36, which allows approximately twice the test current to be applied as compared to schemes which use conventional force and sense connections for force on one line and measurement on the other.

A primary winding 44 of the transformer T1 is fed with alternating pulses of opposite phase via an input device, such as transistors Q1 and Q2 (e.g., switching devices). The return path for the current through either half of the primary winding 44 is via the center tap 46 and a sensing device, such as current shunt R1. The resulting voltage across R1 can be directly utilized to determine the Kelvin contact resistance. In the exemplary implementation the voltage across R1 is inversely proportional to contact resistance. As will be appreciated, other current sensing devices may be utilized, and reference to a resistor as a current sensing device is merely exemplary.

During the contact measurement operation, waveform generator 47 generates alternating pulsed gate waveforms 48 shown in FIG. 3a, which are applied to the gates of Q1 and Q2, respectively. As Q1 and Q2 alternately conduct V+ to the corresponding ends of the primary winding, the resulting alternating voltage applied to the primary winding appears across the secondary winding in relation to the turns ratio of the windings. The voltage V+ preferably is in the range of 5 volts, but V+ can be varied to fit other applications.

Since high currents are typically applied to measure low values of contact resistance, it is then advantageous to utilize a higher turns count on the primary side and a lower turns count on the secondary side. Preferably the turns ratio is on the order of 3:1, primary to secondary. This ratio is optimized to suit the expected Kelvin contact resistance and desired measurement current. Note that each winding 40 and 44 is symmetrical about the center tap (which insures that, during testing, the high current test stimulus will divide evenly; also note the mutual inductance will cancel the series inductance in each of the two secondary high current paths). The secondary voltage is then applied across the Kelvin test contacts and a current will flow in relation to the applied primary voltage turns ratio and the actual contact resistance. Due to the coupling between the primary and secondary windings, a current will flow in the primary circuit 44 of the transformer T1 due to the reflected secondary impedance. This impedance is the contact resistance that is reflected back to the primary winding in relation to the turns ratio of the transformer T1, and this impedance can be determined by the resultant voltage appearing across sensing resistor R1. The resultant voltage across R1 can be used to calculate the contact resistance of the testing contacts.

Due to the arrangement of the circuitry, gate pulses, and phasing of the windings, the voltage appearing at R1 is essentially DC, referenced to ground, and requires no additional detection circuitry. If the turns ratio, applied voltage, and value of R1 are properly chosen so as not to saturate the transformer core, a signal of sufficient amplitude will be developed and additional amplification of the voltage across R1 may not be required. Additionally, the voltage across R1 (or other sensing device) can be provided to a comparator 50. The comparator 50 can be configured to provide an output indicative of whether the measured impedance is acceptable or unacceptable (e.g., above a predetermined threshold, below a predetermined threshold, etc.) Additionally if the voltage across R1 is read by an Analog-to-Digital Converter, the actual Kelvin resistance can be quickly determined.

In any case, an aspect of the invention with the transformer-based Kelvin Resistance measurement and the method to divide the Test Stimulus into two or more current paths, with very low losses, is that the same transformer can be used for both uses. There is no other circuitry required in the high-current path with the Kelvin contacts.

The transformer as described above using a torroid core may be easily designed to have very low capacitance (<5 picofarads) from primary to secondary. Thus, the capacitive loading on the stimulus signal from the Kelvin resistance measurement is very low and allows very high speed transitions. In addition, the pulse circuit may be enabled and provide a correct output of the Kelvin resistance in only tens of microseconds and the circuit is completely passive when turned off.

During the testing of the device, the pulsing of transistors Q1 and Q2 may be stopped, and the test stimulus current is applied to the center tap of the secondary winding. Since the current flows in opposing directions in each half of the winding, no net flux is produced and no currents will appear on the primary. This also cancels out the series inductance of each of the secondary windings so there is essentially no net effect of transformer, and the test stimulus current is efficiently divided into two separate current paths with low losses. In the situation that the currents do not evenly balance due to unequal contact resistance or small variations in the transformer, currents will be induced in the primary winding. By choosing a relatively small magnetic core for the transformer, the energy that is coupled through the transformer before the core saturates is small, and can be easily absorbed by small transient suppressor diodes or Zeners (not shown) to prevent damage to the circuitry in the primary.

If the secondary windings of the transformer are well balanced such that the transformer does not saturate, the pulsing of Q1 and Q2 may be continued during the application of the test stimulus. This provides the ability to monitor the performance of the contact during the high current testing. The magnitude of the voltage appearing across sensing resistor R1 will be essentially the same, assuming the resistance of each line is the same, which will result in balanced currents. It is possible that the resistance values of the two contacts may be quite different and still fall below the acceptable total loop resistance value. This could result in unbalanced currents in the two lines which might not be acceptable in the application. This could also be detected by continuing the pulsing during the application of the test stimulus. Any unbalance of the two paths would result in an AC component appearing across sensing resistor R1 in addition to the average DC level. This could be easily detected and the appropriate action could be taken. If this technique is used, the core of the transformer should be appropriately sized to prevent saturation by the DC component created by the unbalanced load.

The magnetic core, along with the number of turns on the primary winding, are preferably selected such that saturation of the core does not occur at the switching frequency chosen for the drive signal to Q1 and Q2 when the secondary is open circuited. The turns ratio of the primary to secondary can be optimized to provide maximal sensitivity to low contact resistances, while minimizing the power that must be applied to the primary.

The relationships are:

Zₚᵣᵢ/Z_{sec}=(Nₚᵣᵢ/N_{sec})²

i.e., the impedance ratio is equal to the square of the turns ratio

Vᵣ₁=(R1)*(V+)/(Zₚᵣᵢ+R1)

Therefore:

Vᵣ₁=(R1)*(V+)/(R1+((Nₚᵣᵢ/N_{sec})²/Z_{sec}))

Solving for the unknown impedance across the contact points gives:

$${Z}_{sec} = \frac{{( {N}_{pri} / {N}_{sec} )}^{2}}{{R}_{1} ( \frac{v +}{{v}_{{R}_{1}}} - 1 )}$$

Additional parallel paths for the high current stimulus may be added as shown in FIG. 3b. In order to ensure a two-to-one split into the next two transformers, a third transformer is added to the circuit. Circuit operation would be identical to that of FIG. 3a with the addition of a second drive circuit and sense resistor for testing the contact resistance of the second center tapped winding and the third transformer using the secondary windings to split the current equally. Also, other configurations are possible, such as a single primary winding and a star connection of the secondary windings. However, such configuration would provide the parallel combination of the contact resistance, which would need to be taken into account when performing the measurements (e.g., if one contact has a much greater impedance that the other contacts, the parallel combination will be low and thus the “high” impedance contact may be missed).

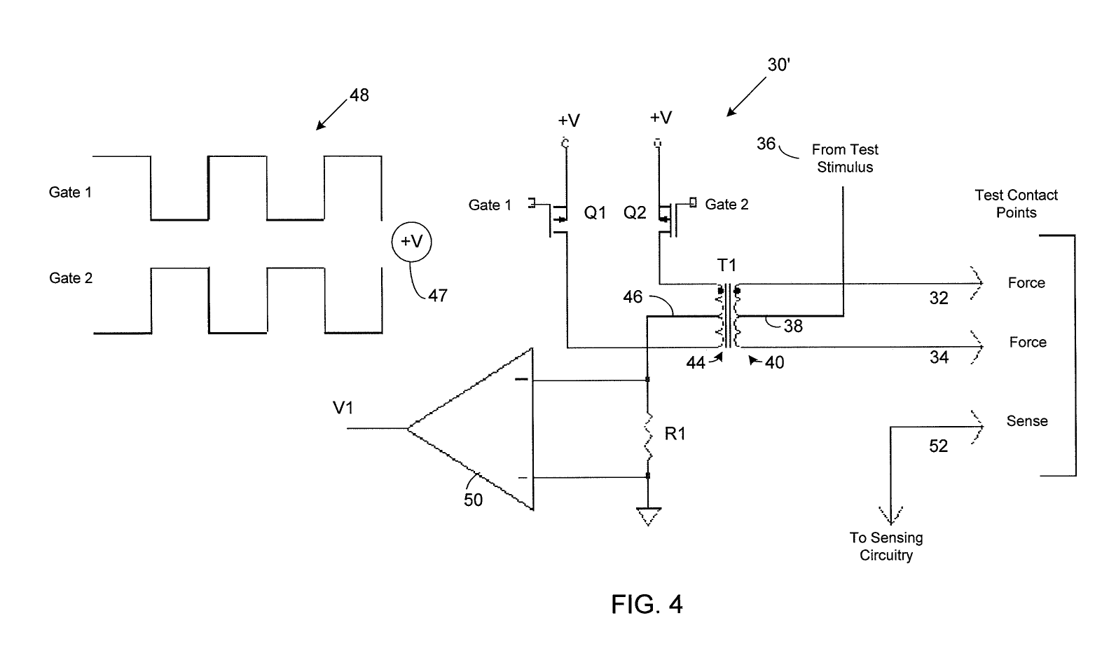

A third lead 52 can be added to the circuit 30′ as shown in FIG. 4 to provide a true Kelvin connected measurement. In this case, a third contact could be used to provide a true measurement sense connection. The high current would then be supplied by the two parallel force leads 30, 32 and the measurement connection made with the third lead 52. Again note the test stimulus current is efficiently divided, without the use of any Kelvin diodes, which results in low losses.

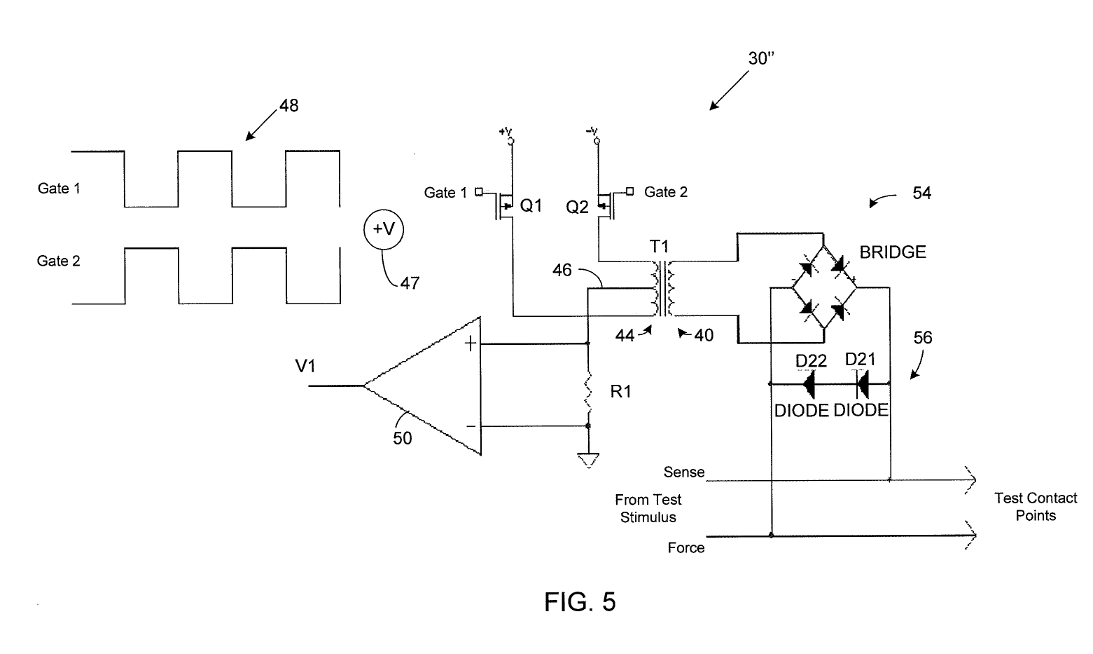

The addition of a full wave bridge rectifier 54 and clamping diodes 56 in the secondary circuit 30″ as shown in FIG. 5 allow the same technique to function for standard force and measure configurations. The circuit functions in exactly the same way to determine the contact resistance of the connections but will include two diode drops in series with the contacts. When the excitation is removed, there are two diode drops between the force lead and sense lead in either direction. Since the contact resistance should be very small these diodes will never become forward biased unless the contacts fail. This insures that the sense (measurement) lead is effectively isolated from the force lead and the clamping action of the diodes may provide protection for sensitive measurement circuitry in the event of a contact failure.

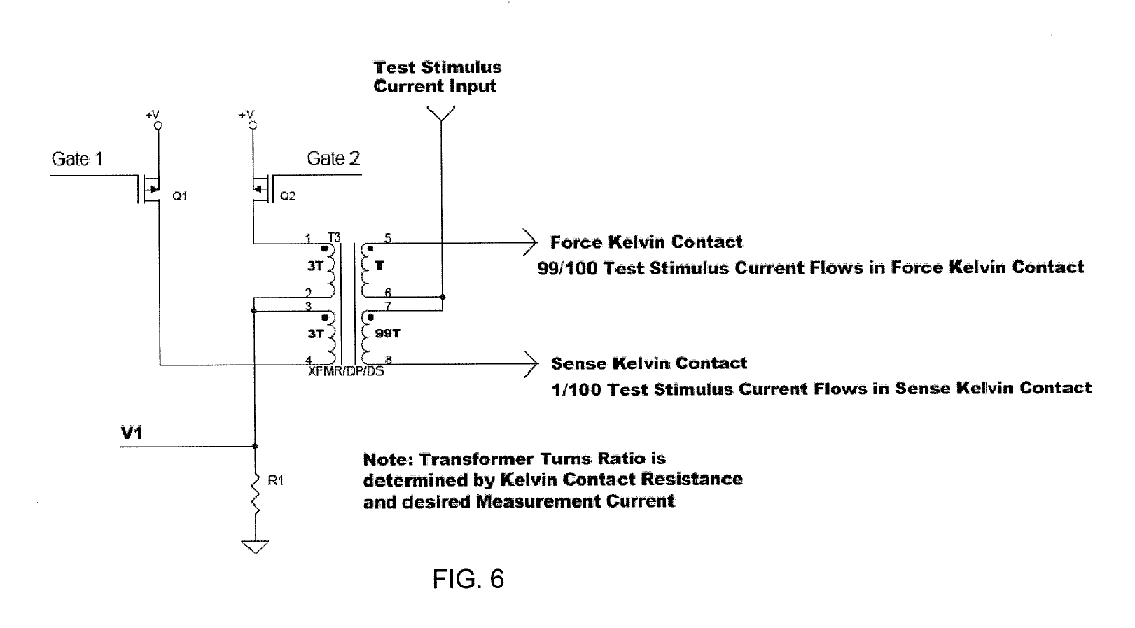

If either the force or sense lead connection should fail during the course of a test, the voltage between the two leads may not exceed two diode drops in either direction. This protection feature allows the Kelvin testing to function, albeit with some error, and prevents high voltages from developing between the force and sense circuitry in the failing condition. FIG. 6 shows that the turns ratio of the transformer controls the current division of the Test Stimulus such that a much lower current path could be used as the Sense Kelvin contact and maintain the ability to verify the connection to the Force Kelvin contact. In other words, the secondary of the transformer can split the current unequally (if desired).

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application. This includes the transformer which can have various winding configurations and turns ratios depending on the particular application. Note in particular that windings may be separately wound or simply center-tapped.

1. A device for measuring contact impedance, comprising:
a transformer having a primary and secondary winding, the primary and secondary winding each having a respective first end, second end, and the primary winding including a center tap;
an input device for receiving an electrical waveform, the input device electrically coupled to the first and second end of the primary winding;
first and second test leads for connection to a device under test, the first and second test leads electrically connected to the first and second ends, respectively, of the secondary winding;
a sensing device electrically coupled to the center tap of the primary winding and configured to provide a measurement corresponding to a contact impedance across at least one of the first and second test leads.

2. The device according to claim 1, wherein the input device comprises a switching device configured to selectively couple the first and second end of the primary winding to the electrical waveform.

3. The device according to claim 2, further comprising a waveform generator for generating the electrical waveform, the waveform generator operatively coupled to the input device.

4. The device according to claim 3, wherein the waveform generator is configured to generate two alternating waveforms out of phase from one another, and the input device provides one of the two alternating waveforms to the first end of the primary winding, and the other of the two alternating waveforms to the second end of the primary winding.

5. The device according to claim 1, wherein the sensing device is configured to measure a current flowing from the center tap of the primary winding to ground.

6. The device according to claim 1, wherein the secondary winding includes a center tap, further comprising a stimulus test lead electrically connected to the center tap of the secondary winding and configured to receive a test signal.

7. The device according to claim 1, further comprising a measurement lead different from the first and second test leads, the measurement lead configured to provide a measurement path for Kelvin connected measurements.

8. The device according to claim 1, further comprising a comparator operatively coupled to the sensing device, the comparator configured to generate a signal indicative of the measured impedance being at least one of above or below a predetermined threshold.

9. A device for measuring contact impedance, comprising:
a transformer having a primary and secondary winding, the primary and secondary winding each having a respective first end and second end, the primary winding further including a center tap;
an input device for receiving an electrical waveform, the input device electrically coupled to the first and second end of the primary winding;
first and second test leads for connection to a device under test;
a rectifier having an input with first and second input connections and an output with first and second output connections, the first and second input connections electrically connected to the first and second end of the secondary winding, respectively, and the first and second output connections connected to the first and second test leads, respectively; and
a sensing device electrically coupled to the primary center tap and configured to provide a measurement corresponding to a contact impedance across at least one of the first and second test leads.

10. The device according to claim 9, wherein the input device comprises a switching device configured to selectively couple the first and second end of the primary winding to the electrical waveform.

11. The device according to claim 9, further comprising a waveform generator for generating the electrical waveform, the waveform generator operatively coupled to the input device.

12. The device according to claim 11, wherein the waveform generator is configured to generate two alternating waveforms out of phase from one another, and the input device provides one of the two alternating waveforms to the first end of the primary winding, and the other of the two alternating waveforms to the second end of the primary winding.

13. The device according to claim 9, wherein the sensing device is configured to measure a current flowing from the primary center tap to ground.

14. The device according to claim 9, further comprising a measurement lead different from the first and second test leads, the measurement lead configured to provide a measurement path for Kelvin connected measurements.

15. The device according to 1 claim 9, further comprising a voltage clamping device connected between the first and second output connections of the rectifier, the voltage clamping means configured to prevent voltage on the first and second output connections from exceeding a predetermined voltage.

16. The device according to claim 9, further comprising a comparator operatively coupled to the sensing device, the comparator configured generate a signal indicative of the measured impedance being at least one of above or below a predetermined threshold.

17. A method for measuring contact impedance, comprising:
connecting each end of a transformer secondary winding to a respective contact of a contact pair to be measured;
applying an alternating current waveform to a primary winding of the transformer;
sensing current flow in a center tap of the primary windings; and
correlating the sensed current flow to the contact impedance.

18. The method according to claim 17, further comprising applying a current stimulus to a center tap of the secondary winding.

19. The method according to claim 17, further comprising comparing the sensed current flow to a predetermined value, and determining if the resistance of the contact pair is acceptable or unacceptable based on the comparison.

20. The method according to claim 19, further comprising enabling application of current stimulus to the respective contacts of the contact pair when the resistance of the contact pair is acceptable, and inhibiting application of current stimulus to the respective contacts of the contact pair when the resistance of the contact pair is unacceptable.

21. The method according to claim 17, further comprising monitoring the sensed current flow for an alternating current (AC) component, and concluding there is an imbalance between the respective contacts of the contact pair when the AC component is above a predetermined threshold.

22. The method according to claim 17, further comprising:
applying a test stimulus current to a center tap of the secondary winding;
dividing the test stimulus current into at least two separate current paths; and
providing the test stimulus current to a respective contact tip via the at least two separate current paths.

23. The method according to claim 17, further comprising minimizing capacitance to ground at the test stimulus input to effect an increase in high-speed stimulus transitions.

24. A method for checking contact impedance, comprising:
connecting secondary leads of a transformer secondary winding to input leads of a rectifier;
connecting output leads of the rectifier to respective ones of a force and sense lead of a contact;
applying an alternating current waveform to primary windings of the transformer;
sensing current flowing to ground in a center tapped lead of the transformer primary windings; and
correlating the sensed current flow to the contact impedance.

25. The method according to claim 24, further comprising connecting a current stimulus device to one output of the rectifier, and connecting a Kelvin connected measurement device to the other output of the rectifier.
